(19) United States
(12) Patent Application Publication
(10) Pub. No.: US 2020/0102454 A1
(43) Pub. Date: Apr. 2, 2020

(54) RESIN COMPOSITION AND ELECTRONIC COMPONENT DEVICE

(71) Applicant: HITACHI CHEMICAL COMPANY, LTD., Tokyo (JP)

(72) Inventors: Dongchul KANG, Chiyoda-ku, Tokyo (JP); Keichi HORI, Chiyoda-ku, Tokyo (JP); Masashi YAMAURA, Chiyoda-ku, Tokyo (JP); Mika TANAKA, Chiyoda-ku, Tokyo (JP)

(21) Appl. No.: 16/473,329

(22) PCT Filed: Dec. 19, 2017
(86) PCT No.: PCT/JP2017/045605

§ 371 Date: Jun. 25, 2019

(30) Foreign Application Priority Data
Dec. 27, 2016 (JP) 2016-253846
Dec. 27, 2016 (JP) 2016-253847

(51) Int. Cl. C08L 63/00; H01L 23/06

(52) U.S. Cl. CPC C08L 63/00; H01L 23/06; C08K 2003/2227; C08K 2201/006; C08K 2201/003

(57) ABSTRACT

A resin composition includes: a resin; and an inorganic filler, in which the inorganic filler includes an inorganic particle having an average particle diameter of from 0.07 μm to 0.5 μm.

### TECHNICAL FIELD

The present invention relates a resin composition and an electronic component device.

### BACKGROUND ART

Packages (electronic component devices) in which elements such as transistors or ICs are sealed with epoxy resins have conventionally been widely used in electronic equipment.

There has recently been a trend towards an increase in the amount of heat generation due to the reduced size and increased density of electronic component devices, and an important issue concerns how to diffuse such heat. As a result, improvements in thermal conductivity have been implemented by mixing inorganic fillers having high thermal conductivity with sealants.

In cases of mixing an inorganic filler with a sealant, a problem of filling failure, for example, may occur because the viscosity of a sealant increases while the fluidity thereof decreases owing to an increase in the amount of inorganic filler. A method of enhancing the fluidity of a sealant by using a specific phosphorus compound as a curing accelerator has been proposed (see, for example, Patent Document 1).

### CITATION LIST

### Patent Document

Patent Document 1: Japanese Patent Application Laid-Open (JP-A) No. H09-157497

### SUMMARY OF INVENTION

### Technical Problem

As reductions in the size, and increases in the density, of electronic component devices are further advanced, there is demand for a resin composition that can be used as a sealant having superior fluidity while maintaining a high level of thermal conductivity.

The invention has been made in view of such circumstances, and aims to provide a resin composition having superior fluidity, and an electronic component device including an element sealed with the resin composition.

### Solution to Problem

Means of solving the problem encompass the following aspects.

<1> A resin composition, including:

a resin; and

an inorganic filler,

wherein the inorganic filler includes an inorganic particle having an average particle diameter of from 0.07 μm to 0.5 μm.

<2> The resin composition according to <1>, wherein the inorganic particle has a specific surface area of 15 m²/g or less.
<3> The resin composition according to <1> or <2>, wherein a proportion of the inorganic particle in the entire inorganic filler is from 3% by mass to 10% by mass.
<4> The resin composition according to any one of <1> to <3>, wherein the inorganic particle is an alumina particle.
<5> The resin composition according to any one of <1> to <4>, wherein a proportion of the inorganic particle in the entire inorganic filler is from 3% by mass to 10% by mass.
<6> The resin composition according to any one of <1> to <5>, wherein:

the inorganic filler includes the inorganic particle and an additional inorganic particle different from the inorganic particle; and

a ratio (A/B) of a specific gravity A of the inorganic particle to a specific gravity B of the additional inorganic particle different from the inorganic particle is from 0.8 to 1.2.

<7> The resin composition according to any one of <1> to <6>, wherein:

the inorganic filler includes the inorganic particle and an additional inorganic particle different from the inorganic particle; and

the additional inorganic particle different from the inorganic particle includes an inorganic particle made of the same material as the inorganic particle.

<8> The resin composition according to any one of <1> to <7>, for use in a sealant for an electronic component device.
<9> An electronic component device, including:

an element; and

a cured product of the resin composition according to any one of <1> to <7> sealing the element.

<10> A resin composition, including:

a resin; and

an inorganic filler,

wherein the inorganic filler includes an inorganic particle A having a volume average particle diameter of from 0.07 μm to 0.5 μm, and an inorganic particle B different from the inorganic particle A, and

a ratio (A/B) of a refractive index A of a material that is a component of the inorganic particle A to a refractive index B of a material that is a component of the inorganic particle B is from 0.9 to 1.5.

### Advantageous Effect of Invention

According to the invention, a resin composition having superior fluidity, and an electronic component device including an element sealed with the resin composition are provided.

### DESCRIPTION OF EMBODIMENTS

Hereinafter, embodiments for carrying out the invention will be described in detail, but the invention is not limited to the following embodiments. The components (encompassing, for example, elemental steps) in the following embodiments are not essential, unless particularly specified. The same is also true on the numerical values and the ranges thereof, and the invention is not intended to be limited.

The term “step” in the present disclosure encompasses not only an independent step, but also a step that is not clearly distinguished from other steps unless a predetermined object of such a step is achieved.

The numerical value range in the disclosure, represented by “(from) . . . to . . . ”, means that the numerical values described before and after “to” are encompassed as the lower limit and the upper limit, respectively.

The upper limit or the lower limit described in one numerical value range described in a stepwise manner may be replaced with the upper limit or the lower limit described in other numerical value range described in a stepwise manner, in the disclosure. The upper limit or the lower limit described in such a numerical value range described in the disclosure may also be replaced with any value described in Examples.

The content rate or content of each component in any composition in the disclosure means the total content rate or content of plural kinds of substances corresponding to the component, present in the composition, in a case in which such plural kinds of substances are present in the composition, unless particularly noted.

The particle diameter of each component in any composition in the disclosure means the particle diameter value of a mixture of plural kinds of particles corresponding to the component, present in the composition, in a case in which such plural kinds of particles are present in the composition, unless particularly noted.

<Resin Composition>

A resin composition according to one embodiment of the disclosure includes: a resin; and an inorganic filler, in which the inorganic filler includes an inorganic particle having a volume average particle diameter of 0.07 μm to 0.5 μm (hereinafter, also referred to as “specific inorganic particle”).

The inventors have made studies and thus have found that a resin composition in which an inorganic filler includes a specific inorganic particle has superior fluidity as compared with a resin composition in which an inorganic filler includes no specific inorganic particle.

Although the reason why the resin composition in which an inorganic filler includes a specific inorganic particle has superior fluidity is not necessarily clear, one reason is considered because such a specific inorganic particle is present between such inorganic fillers (i.e., large size particles) having a larger particle diameter, thereby resulting in a reduction in frictional resistance between the large size particles.

The inventors have conducted further research and have found that the effect of improving fluidity is not obtained in a case in which the inorganic particle included in the inorganic filler has a volume average particle diameter of less than 0.07 μm or more than 0.5 μm. Although the reason for this is not necessarily clear, it is assumed that the function of reducing the frictional resistance between the large size particles is not exerted owing to, for example, the formation of aggregates of an inorganic particle having a volume average particle diameter of less than 0.07 μm between the large size particles, or owing to the presence of an inorganic particle having a volume average particle diameter of more than 0.5 μm between the large size particles, leading to actual prevention of the movement of the large size particles.

The specific inorganic particle preferably has a volume average particle diameter of 0.4 μm or less, more preferably 0.3 μm or less, and still more preferably 0.2 μm or less.

The volume average particle diameter of the specific inorganic particle in the disclosure means a particle diameter (D50) at an accumulation of 50% from the smaller size in the particle size distribution on a volume basis measured in a wet dispersion with a laser diffraction particle size distribution analyzer (“Mastersizer 3000” available from Malvern Instruments Ltd.).

The particle size distribution of the specific inorganic particle is not particularly limited, and it is preferable that the proportion of fine particles is smaller from the viewpoint of suppression of particle aggregation. Specifically, for example, the specific surface area of the entire specific inorganic particle is preferably 15 m²/g or less, and more preferably 10 m²/g or less. The specific surface area of the specific inorganic particle corresponds to a value obtained by measurement according to the BET method using “Multisorb 16” available from YUASA IONICS.

The proportion of the specific inorganic particle in the entire inorganic filler is not particularly limited. The proportion of the specific inorganic particle in the entire inorganic filler is preferably from 3% by mass to 10% by mass from the viewpoint that the effect of improving fluidity by the specific inorganic particle is sufficiently obtained. It is more preferable that the proportion of the specific inorganic particle in the entire inorganic filler is from 3% by mass to 10% by mass and the volume average particle diameter of the entire inorganic filler is from 0.2 μm to 20 The details of the inorganic filler are described below.

The shape of the specific inorganic particle is not particularly limited. A more preferable shape is a shape closer to a spherical shape, from the viewpoint that the effect of enhancing fluidity by the specific inorganic particle is sufficiently obtained. Specifically, for example, the specific inorganic particle preferably has a degree of circularity of 0.70 or more, observed with an electron microscope. The degree of circularity corresponds to a value represented by 4π×S/(perimeter)², where S represents the area of a measurement particle and the perimeter is the perimeter of a measurement particle. The degree of circularity can be determined by analysis of an electron microscope image with image processing software.

A material of the specific inorganic particle is not particularly limited. Examples of the material include inorganic materials such as silica, alumina, calcium carbonate, zirconium silicate, calcium silicate, silicon nitride, aluminum nitride, boron nitride, beryllia, zirconia, zircon, fosterite, steatite, spinel, mullite, titania, talc, clay, or mica. The material may also be a flame-retardant inorganic material. Examples of the flam-retardant inorganic material include aluminum hydroxide, magnesium hydroxide, composite metal hydroxides such as a composite hydroxide of magnesium and zinc, and zinc borate. The material of the specific inorganic particle may be used singly, or in combination of two or more kinds thereof. The specific inorganic particle is preferably an alumina particle (specific alumina particle).

The material of the specific inorganic particle may be at least one selected from materials having a refractive index ranging from 1.0 to 2.0.

The refractive index in the disclosure corresponds to a value unique for a substance under the assumption that the vacuum corresponds to 1 (absolute refractive index), and corresponds to a value with respect to light at a wavelength of 589.3 nm.

(Resin)

The resin included in the resin composition may be a thermosetting, thermoplastic, or photo-curable resin. The resin is preferably a curable resin from the viewpoint of reliability. The curable resin may be to be cured by self-polymerization or by a reaction with, for example, a curing agent or a crosslinking agent.

In a case in which the resin is a curable resin, the functional group that contributes to the occurrence of such a reaction is not particularly limited, and examples thereof include cyclic ether groups such as an epoxy group or an oxetanyl group, a hydroxyl group, a carboxyl group, an amino group, an acryloyl group, and an isocyanate group. A curable resin containing a cyclic ether group is preferable, and a curable resin containing an epoxy group (epoxy resin) is more preferable, from the viewpoint of the balance of characteristics of a sealant.

In a case in which the curable resin is an epoxy resin, the epoxy resin is not particularly limited in terms of the type thereof as long as the epoxy resin has an epoxy group in the molecule thereof.

Examples of the epoxy resin include: novolac-type epoxy resins (such as a phenol novolac epoxy resin or an o-cresol novolac epoxy resin) that are epoxidized products of novolac resins each obtained by condensation or co-condensation of at least one phenolic compound selected from the group consisting of phenol compounds such as phenol, cresol, xylenol, resorcin, catechol, bisphenol A or bisphenol F and naphthol compounds such as α-naphthol, β-naphthol or dihydroxynaphthalene with an aliphatic aldehyde compound such as formaldehyde, acetaldehyde or propionaldehyde in the presence of an acidic catalyst; triphenylmethane-type epoxy resins that are epoxidized products of triphenylmethane phenol resins each obtained by condensation or co-condensation of the phenolic compound with an aromatic aldehyde compound such as benzaldehyde or salicylaldehyde in the presence of an acidic catalyst; copolymerized epoxy resins that are epoxidized products of novolac resins each obtained by co-condensation of the phenol compound and the naphthol compound with the aldehyde compound in the presence of an acidic catalyst; diphenylmethane epoxy resins as diglycidyl ethers of bisphenol A, bisphenol F, and the like; biphenyl epoxy resins as diglycidyl ethers of alkyl-substituted or unsubstituted biphenols; stilbene epoxy resins as diglycidyl ethers of stilbene-based phenol compounds; sulfur atom-containing epoxy resins as diglycidyl ethers of bisphenol S or the like; epoxy resins as diglycidyl ethers of alcohols such as butanediol, polyethylene glycol, or polypropylene glycol; glycidyl ester epoxy resins that are diglycidyl ethers of polyvalent carboxylic acid compounds such as phthalic acid, isophthalic acid, or tetrahydrophthalic acid; glycidyl amine epoxy resins in which active hydrogen bound to any nitrogen atom of aniline, diaminodiphenylmethane, isocyanuric acid, or the like is substituted with a glycidyl group; dicyclopentadiene epoxy resins that are epoxidized products of co-condensed resins of dicyclopentadiene and a phenol compound; alicyclic epoxy resins as products each obtained by epoxidation of an olefin bond in a molecule of vinylcyclohexene diepoxide, 3,4-epoxycyclohexylmethyl-3,4-epoxycyclohexane carboxylate, 2-(3,4-epoxy)cyclohexyl-5,5-spiro(3,4-epoxy)cyclohexane-m-dioxane, or the like; paraxylene-modified epoxy resins as glycidyl ethers of paraxylene-modified phenol resins; metaxylene-modified epoxy resins as glycidyl ethers of metaxylene-modified phenol resins; terpene-modified epoxy resins as glycidyl ethers of terpene-modified phenol resins; dicyclopentadiene-modified epoxy resins as glycidyl ethers of dicyclopentadiene-modified phenol resins; cyclopentadiene-modified epoxy resins as glycidyl ethers of cyclopentadiene-modified phenol resins; polycyclic aromatic ring-modified epoxy resins as glycidyl ethers of polycyclic aromatic ring-modified phenol resins; naphthalene-type epoxy resins as glycidyl ethers of naphthalene ring-containing phenol resins; halogenated phenol novolac epoxy resins; hydroquinone-type epoxy resins; trimethylolpropane-type epoxy resins; linear aliphatic epoxy resins each obtained by oxidation of an olefin bond with peracid such as peracetic acid; and aralkyl epoxy resins that are epoxidized products of aralkyl phenol resins such as a phenol aralkyl resin or a naphthol aralkyl resin. Furthermore, examples of the epoxy resin include epoxidized products of silicone resins and epoxidized products of acrylic resins. Such epoxy resins may be used singly, or in combination of two or more kinds thereof.

The epoxy equivalent (i.e., molecular weight/number of epoxy groups) of the epoxy resin is not particularly limited. The epoxy equivalent is preferably 100 g/eq to 1000 g/eq, and more preferably 150 g/eq to 500 g/eq, from the viewpoint of the balance among various characteristics such as moldability, reflow resistance, and electrical reliability.

The epoxy equivalent of the epoxy resin is defined as a value measured by the method according to JIS K7236: 2009.

The softening temperature or the melting temperature of the resin is not particularly limited. The softening temperature or the melting temperature is preferably from 40° C. to 180° C. from the viewpoints of moldability and reflow resistance, and is more preferably from 50° C. to 130° C. from the viewpoint of handleability in preparation of the resin composition.

The softening temperature or the melting temperature of the resin is defined as a value measured by the single cylinder-type rotational viscometer method described in JIS K7234: 1986 and JIS K7233: 1986.

The content rate of the epoxy resin in a curable resin composition is preferably from 0.5% by mass to 50% by mass, and more preferably from 2% by mass to 30% by mass, from the viewpoint of strength, fluidity, heat resistance, moldability, and the like.

(Curing Agent)

The resin composition may include a curing agent. The type of the curing agent is not particularly limited, and can be selected depending on, for example, the type of the resin and desired characteristics of the resin composition.

In a case in which the resin is an epoxy resin, examples of the curing agent include a phenol curing agent, an amine curing agent, an acid anhydride curing agent, a polymercaptan curing agent, a polyaminoamide curing agent, an isocyanate curing agent, and a block isocyanate curing agent. The curing agent is preferably a curing agent (phenol curing agent) having a phenolic hydroxyl group in a molecule thereof from the viewpoint of an enhancement in heat resistance.

Specific examples of the phenol curing agent include: polyhydric phenol compounds such as resorcin, catechol, bisphenol A, bisphenol F, or substituted or unsubstituted biphenol; novolac phenol resins each obtained by condensation or co-condensation of at least one phenolic compound selected from the group consisting of phenol compounds such as phenol, cresol, xylenol, resorcin, catechol, bisphenol A, bisphenol F, phenylphenol, or aminophenol and naphthol compounds such as α-naphthol, β-naphthol, or dihydroxynaphthalene with an aldehyde compound such as formaldehyde, acetaldehyde, propionaldehyde, benzaldehyde, or salicylaldehyde in the presence of an acidic catalyst; aralkyl-type phenol resins such as a phenol aralkyl resin or a naphthol aralkyl resin each synthesized from the phenolic compound with dimethoxy para-xylene or bis(methoxymethyl)biphenyl or the like; paraxylene and/or metaxylene-modified phenol resins; melamine-modified phenol resins; terpene-modified phenol resins; dicyclopentadiene phenol resins and dicyclopentadiene naphthol resins each synthesized by co-condensation of the phenolic compound with dicyclopentadiene; cyclopentadiene-modified phenol resins; polycyclic aromatic ring-modified phenol resins; biphenyl phenol resins; triphenylmethane phenol resins each obtained by condensation or co-condensation of the phenolic compound with an aromatic aldehyde compound such as benzaldehyde or salicylaldehyde in the presence of an acidic catalyst; and phenol resins each obtained by copolymerization of two or more thereof. Such phenol curing agents may be used singly, or in combination of two or more kinds thereof.

The functional group equivalent (e.g., hydroxyl group equivalent in a case of a phenol curing agent) of the curing agent is not particularly limited. The functional group equivalent is preferably from 70 g/eq to 1000 g/eq, and more preferably from 80 g/eq to 500 g/eq, from the viewpoint of the balance among various characteristics such as moldability, reflow resistance, and electrical reliability.

The functional group equivalent (e.g., hydroxyl group equivalent in a case of a phenol curing agent) of the curing agent is defined as a value measured by the method according to JIS K0070: 1992.

The softening temperature or the melting temperature of the curing agent is not particularly limited. The softening temperature or the melting temperature is preferably from 40° C. to 180° C. from the viewpoints of moldability and reflow resistance, and is more preferably from 50° C. to 130° C. from the viewpoint of handleability in production of a curable resin composition.

The softening temperature or the melting temperature of the curing agent is defined as a value measured by the single cylinder-type rotational viscometer method described in JIS K7234: 1986 and JIS K7233: 1986.

The equivalent ratio of the curing agent to the curable resin, namely, the ratio of the number of functional groups in a curing agent with respect to the number of functional groups in a curable resin (i.e., the number of functional groups in a curing agent/the number of functional groups in a curable resin) is not particularly limited. The equivalent ratio is preferably set in a range of from 0.5 to 2.0, and more preferably set in a range of from 0.6 to 1.3, from the viewpoint that the amounts of respective unreacted components are suppressed to small amounts. The equivalent ratio is still more preferably set in a range of from 0.8 to 1.2 from the viewpoint of moldability and reflow resistance.

(Curing Accelerator)

The resin composition may include a curing accelerator. The type of the curing accelerator is not particularly limited, and can be selected depending on, for example, the type of the resin and desired characteristics of the resin composition.

Examples of the curing accelerator include: diazabicycloalkenes such as 1,5-diazabicyclo[4.3.0]nonene-5 (DBN) or 1,8-diazabicyclo[5.4.0]undecene-7 (DBU); cyclic amidine compounds such as 2-methylimidazole, 2-phenyl imidazole, 2-phenyl-4-methylimidazole, or 2-heptadecylimidazole; derivatives of the cyclic amidine compounds; phenol novolac salts of the cyclic amidine compounds or derivatives thereof; compounds having intramolecular polarization, each obtained by adding, to such a compound, a π-bond-bearing compound such as maleic anhydride, a quinone compound such as 1,4-benzoquinone, 2,5-toluquinone, 1,4-naphthoquinone, 2,3-dimethylbenzoquinone, 2,6-dimethylbenzoquinone, 2,3-dimethoxy-5-methyl-1,4-benzoquinone, 2,3-dimethoxy-1,4-benzoquinone or phenyl-1,4-benzoquinone, or diazophenylmethane; cyclic amidinium compounds such as tetraphenyl borate salt of DBU, tetraphenyl borate salt of DBN, tetraphenyl borate salt of 2-ethyl-4-methylimidazole, and tetraphenyl borate salt of N-methylmorpholine; tertiary amine compounds such as pyridine, triethylamine, triethylenediamine, benzyldimethylamine, triethanolamine, dimethylaminoethanol, or tris(dimethylaminomethyl)phenol; derivatives of the tertiary amine compounds; ammonium salt compounds such as tetra-n-butyl ammonium acetate, tetra-n-butyl ammonium phosphate, tetraethyl ammonium acetate, tetra-n-hexyl ammonium benzoate, or tetrapropyl ammonium hydroxide; tertiary phosphines such as triphenyl phosphine, diphenyl (p-tolyl)phosphine, tris(alkylphenyl)phosphine, tris(alkoxyphenyl)phosphine, tris(alkyl-alkoxyphenyl)phosphine, tris(dialkylphenyl)phosphine, tris(trialkylphenyl)phosphine, tris(tetraalkylphenyl)phosphine, tris(dialkoxyphenyl)phosphine, tris(trialkoxyphenyl)phosphine, tris(tetraalkoxyphenyl)phosphine, trialkylphosphine, dialkylaryl phosphine, or alkyl diaryl phosphine; phosphine compounds such as complexes of the tertiary phosphines with organoborons; compounds having intramolecular polarization, each obtained by adding such tertiary phosphine or such a phosphine compound, and a compound having a n-bond, for example, maleic anhydride, a quinone compound such as 1,4-benzoquinone, 2,5-toluquinone, 1,4-naphthoquinone, 2,3-dimethylbenzoquinone, 2,6-dimethylbenzoquinone, 2,3-dimethoxy-5-methyl-1,4-benzoquinone, 2,3-dimethoxy-1,4-benzoquinone or phenyl-1,4-benzoquinone, or diazophenylmethane; compounds having intramolecular polarization, each obtained by a reaction of such tertiary phosphine or such a phosphine compound with a halogenated phenol compound such as 4-bromophenol, 3-bromophenol, 2-bromophenol, 4-chlorophenol, 3-chlorophenol, 2-chlorophenol, 4-iodophenol, 3-iodophenol, 2-iodophenol, 4-bromo-2-methylphenol, 4-bromo-3-methylphenol, 4-bromo-2,6-dimethylphenol, 4-bromo-3,5-dimethylphenol, 4-bromo-2,6-di-tert-butylphenol, 4-chloro-1-naphthol, 1-bromo-2-naphthol, 6-bromo-2-naphthol or 4-bromo-4′-hydroxybiphenyl, followed by a dehydrohalogenation step; tetrasubstituted phosphonium such as tetraphenyl phosphonium, and tetrasubstituted phosphonium and tetrasubstituted borate not containing any phenyl group bound to a boron atom, such as tetra-p-tolylborate; and salts of tetraphenyl phosphonium and phenol compounds.

In a case in which the resin composition includes such a curing accelerator, the amount of the curing accelerator is preferably from 0.1 parts by mass to 30 parts by mass, and more preferably from 1 part by mass to 15 parts by mass, with respect to 100 parts by mass of the resin components (i.e., the total of the resin and the curing agent included if necessary). An amount of the curing accelerator of 0.1 parts by mass or more with respect to 100 parts by mass of the resin component tends to allow favorable curing to be achieved in a short time. An amount of the curing accelerator of 30 parts by mass or less with respect to 100 parts by mass of the resin component tends to allow a favorable molded article to be obtained due to a curing speed which is not too high.

(Inorganic Filler)

The inorganic filler included in the resin composition is not particularly limited as long as the inorganic filler includes the specific inorganic particle.

Specific examples of a material of the inorganic filler include inorganic materials such as molten silica, crystalline silica, glass, alumina, calcium carbonate, zirconium silicate, calcium silicate, silicon nitride, aluminum nitride, boron nitride, beryllia, zirconia, zircon, fosterite, steatite, spinel, mullite, titania, talc, clay, or mica. A flame-retardant inorganic filler may be used. Examples of such a flame-retardant inorganic filler include aluminum hydroxide, magnesium hydroxide, a composite metal hydroxide such as a composite hydroxide of magnesium and zinc, and zinc borate.

Among the inorganic fillers, silica such as molten silica is preferable from the viewpoint of a reduction in linear expansion coefficient, and alumina is preferable from the viewpoint of high thermal conductance. Such inorganic fillers may be used singly, or in combination of two or more kinds thereof.

In a case in which the inorganic filler is particulate, the average particle diameter thereof is not particularly limited. For example, the volume average particle diameter of the entire inorganic filler is preferably from 0.2 μm to 20 and more preferably from 0.5 μm to A volume average particle diameter of the inorganic filler of 0.2 μm or more tends to allow an increase in the viscosity of the resin composition to be more suppressed. A volume average particle diameter of 15 μm or less tends to allow filling properties of a narrow gap to be more enhanced. The volume average particle diameter of the inorganic filler can be measured as the particle diameter (D50) at an accumulation of 50% from the smaller size in the particle size distribution on a volume basis measured with a laser scattering particle size distribution analyzer.

The inorganic filler preferably includes the specific inorganic particle and an additional inorganic particle different from the specific inorganic particle, and such an additional inorganic particle different from the specific inorganic particle is preferably included in an amount such that the amount of the specific inorganic particle would be from 3% by mass to 10% by mass relative to the entire inorganic fillers.

In a case in which the inorganic filler includes the specific inorganic particle and an additional inorganic particle different from the specific inorganic particle, such an additional inorganic particle different from the specific inorganic particle preferably includes an inorganic particle made of the same material as the specific inorganic particle. For example, in a case in which the specific inorganic particle is an alumina particle, such an additional inorganic particle different from the specific inorganic particle preferably includes an alumina particle.

The average particle diameter of such an additional inorganic particle different from the specific inorganic particle is preferably an average particle diameter such that the volume average particle diameter of the entire inorganic fillers falls within the above-mentioned ranges. For example, the volume average particle diameter is preferably from 0.2 μm to 20 μm, and more preferably from 0.5 μm to 15 μm.

The ratio (A/B) of the specific gravity A of the specific inorganic particle to the specific gravity B of such an additional inorganic particle different from the specific inorganic particle is preferably from 0.8 to 1.2, more preferably from 0.9 to 1.1, and still more preferably from 0.95 to 1.05, from the viewpoint of an enhancement in fluidity of the resin composition. In a case in which the specific gravity A of the specific inorganic particle and the specific gravity B of such an additional inorganic particle different from the specific inorganic particle satisfy the above condition, the effect of enhancing fluidity tends to be easily exerted because the specific inorganic particle and such an additional inorganic particle are hardly separated and the specific inorganic particle easily penetrates between such an additional inorganic particles in the resin composition. In a case in which any or both of the specific inorganic particle and such an additional inorganic particle are combinations of two or more kinds thereof, it is more preferable that the respective materials satisfy the above-mentioned relationship.

The ratio (A/B) of the refractive index A of a material that is a component of the specific inorganic particle with respect to the refractive index B of a material that is a component of such an additional inorganic particle different from the specific inorganic particle included in the inorganic filler is preferably from 0.9 to 1.5, more preferably from 1.0 to 1.4, and still more preferably from 1.1 to 1.3, from the viewpoint of an enhancement in fluidity of the resin composition. In a case in which the refractive index A of a material that is a component of the specific inorganic particle and the refractive index B of a material that is a component of such an additional inorganic particle different from the specific inorganic particle satisfy the above-mentioned condition, the effect of enhancing fluidity tends to be easily exerted because the specific inorganic particle and such an additional inorganic particle are hardly separated and the specific inorganic particle easily penetrates between such an additional inorganic particles in the resin composition. In a case in which any or both of the specific inorganic particle and such an additional inorganic particle are combinations of two or more kinds thereof, it is more preferable that the respective materials satisfy the above-mentioned relationship.

The content rate of the inorganic filler in the resin composition is not particularly limited. The content rate with respect to the entire resin composition is preferably from 30% by volume to 90% by volume, more preferably from 35% by volume to 80% by volume, and still more preferably from 40% by volume to 70% by volume, from the viewpoints of fluidity and strength. A content rate of the inorganic filler of 30% by volume or more with respect to the entire resin composition tends to result in more enhancements in characteristics such as thermal expansion coefficient, thermal conductivity, and elastic modulus of a cured product. A content rate of the inorganic filler of 90% by volume or less with respect to the entire resin composition tends to allow an increase in the viscosity of the resin composition to be suppressed, resulting in a more enhancement in fluidity and more favorable moldability.

[Various Additives]

The resin composition may include various additives exemplified below, such as a coupling agent, an ion exchanger, a release agent, a flame retardant, a colorant, or a stress relaxation agent, in addition to the above components. The resin composition may also include, if necessary, various additives well-known in the art, in addition to the additives exemplified below.

(Coupling Agent)

The resin composition may include a coupling agent in order to improve adhesiveness between the resin component and the inorganic filler. Examples of the coupling agent include known coupling agents including silane-based compounds such as epoxysilane, mercaptosilane, aminosilane, alkylsilane, ureidosilane, or vinylsilane, titanium-based compounds, aluminum chelate compounds, and aluminum/zirconium-based compounds.

In a case in which the resin composition includes a coupling agent, the amount of the coupling agent is preferably from 0.05 parts by mass to 5 parts by mass, and more preferably from 0.1 parts by mass to 2.5 parts by mass, with respect to 100 parts by mass of the inorganic filler. An amount of a coupling agent of 0.05 parts by mass or more with respect to 100 parts by mass of the inorganic filler tends to result in a more enhancement in adhesiveness to a frame. An amount of a coupling agent of 5 parts by mass or less with respect to 100 parts by mass of the inorganic filler tends to result in a more enhancement in moldability of a package.

(Ion Exchanger)

The curable resin composition may include an ion exchanger. In particular, in a case in which the curable resin composition is used as a molding material for sealing, the curable resin composition preferably includes an ion exchanger from the viewpoint of enhancements in moisture resistance and high-temperature shelf properties of an electronic component device including an element to be sealed. The ion exchanger is not particularly limited, and a conventionally known ion exchanger may be used. Specific examples of the ion exchanger include hydrotalcite compounds, and hydroxides containing at least one element selected from the group consisting of magnesium, aluminum, titanium, zirconium and bismuth. Such ion exchangers may be used singly, or in combination of two or more kinds thereof. In particular, hydrotalcite represented by the following Formula (A) is preferable.

Mg_{(1-X)}Al_{X}(OH)₂(CO₃)_{X/2}.mH₂O (A)

(0<X≤0.5, m represents a positive number)

In a case in which the resin composition includes an ion exchanger, the content of the ion exchanger is not particularly limited as long as the content is satisfactory for capture of ions such as a halogen ion. For example, the content is preferably from 0.1 parts by mass to 30 parts by mass, and more preferably from 1 part by mass to 10 parts by mass, with respect to 100 parts by mass of the resin component.

(Release Agent)

The resin composition may include a release agent from the viewpoint that favorable releasability from a mold in molding is obtained. The release agent is not particularly limited, and a conventionally known release agent may be used. Specific examples thereof include carnauba wax, higher fatty acids such as montanic acid or stearic acid, metal salts of higher fatty acids, ester-based waxes such as montanate, and polyolefin-based waxes such as oxidized polyethylene or non-oxidized polyethylene. Such release agents may be used singly, or in combination of two or more kinds thereof.

In a case in which the resin composition includes a release agent, the amount of the release agent is preferably from 0.01 parts by mass to 10 parts by mass, and more preferably from 0.1 parts by mass to 5 parts by mass, with respect to 100 parts by mass of the resin component. An amount of a release agent of 0.01 parts by mass or more with respect to 100 parts by mass of the resin component tends to allow releasability to be satisfactorily obtained. An amount of 10 parts by mass or less tends to allow more favorable adhesiveness to be obtained.

(Flame Retardant)

The resin composition may include a flame retardant. The flame retardant is not particularly limited, and a conventionally known flame retardant may be used. Specific examples thereof include organic or inorganic compounds containing a halogen atom, an antimony atom, a nitrogen atom or a phosphorus atom, and metal hydroxides. Such flame retardants may be used singly, or in combination of two or more kinds thereof.

In a case in which the resin composition includes a flame retardant, the amount of the flame retardant is not particularly limited as long as the amount is satisfactory for imparting a desired flame-retardant effect. For example, the amount is preferably from 1 part by mass to 30 parts by mass, and more preferably from 2 parts by mass to 20 parts by mass, with respect to 100 parts by mass of the resin component.

(Colorant)

The resin composition may further include a colorant. Examples of the colorant include known colorants such as carbon black, an organic dye, an organic pigment, titanium oxide, red lead, and colcothar. The content of the colorant may be appropriately selected depending on, for example, the purpose. Such colorants may be used singly, or in combination of two or more kinds thereof.

(Stress Relaxation Agent)

The resin composition may include a stress relaxation agent such as silicone oil or a silicone rubber particle. When the resin composition includes a stress relaxation agent, further reductions in warpage and decomposition of a package and in the occurrence of package cracks may be achieved. Examples of the stress relaxation agent include known stress relaxation agents (flexible materials) commonly used. Specific examples thereof include silicone-based, styrene-based, olefin-based, urethane-based, polyester-based, polyether-based, polyamide-based, and polybutadiene-based thermoplastic elastomers, rubber particles of NR (natural rubber), NBR (acrylonitrile-butadiene rubber), acrylic rubber, urethane rubber, silicone powders and the like, and rubber particles having a core-shell structure, such as particles of a methyl methacrylate-styrene-butadiene copolymer (MBS), a methyl methacrylate-silicone copolymer, a methyl methacrylate-butyl acrylate copolymer and the like. Such stress relaxation agents may be used singly, or in combination of two or more kinds thereof

(Method of Preparing Resin Composition)

The method of preparing the resin composition is not particularly limited. Examples of a common procedure can include a method involving satisfactorily mixing predetermined compounding amounts of components using, for example, a mixer, then melt-kneading the resulting mixture using, for example, a mixing roll or an extruder, and cooling and pulverizing the resultant. More specific examples can include a method involving uniformly stirring and mixing the predetermined compounding amounts of components, kneading the resulting mixture using, for example, a kneader or an extruder heated in advance to from 70° C. to 140° C., and cooling and pulverizing the resultant.

It is preferable that the resin composition is a solid at an ordinary temperature and an ordinary pressure (for example, at 25° C. and atmospheric pressure). The shape of the resin composition when the resin composition is solid is not particularly limited, and examples include powder, particle, and tablet shapes. The dimension and mass of a tablet-shaped resin composition are preferably set so as to be any dimension and any mass adapted to molding conditions of a package, respectively, from the viewpoint of handleability.

<Electronic Component Device>

An electronic component device according to an embodiment of the disclosure includes: an element; and a cured product of the resin composition sealing the element.

Examples of the electronic component device include devices in which an element unit obtained by mounting any element (examples thereof include active elements such as a semiconductor chip, a transistor, a diode, and a thyristor, and passive elements such as a capacitor, a resistor, and a coil) on a support member such as a lead frame, a wired tape carrier, a wiring board, glass, a silicon wafer, or an organic board is sealed with the resin composition.

More specific examples can include: general resin-sealed ICs such as DIP (Dual Inline Package), PLCC (Plastic Leaded Chip Carrier), QFP (Quad Flat Package), SOP (Small Outline Package), SOJ (Small Outline J-lead package), TSOP (Thin Small Outline Package), or TQFP (Thin Quad Flat Package) each having a structure obtained by securing any element on a lead frame, connecting a terminal unit of an element such as a bonding pad to a lead unit according to, for example, wire bonding or bump, and then sealing the resultant with the resin composition according to transfer molding; TCP (Tape Carrier Package) having a structure obtained by sealing an element connected to a tape carrier according to bump, with the resin composition; COB (Chip On Board) module, hybrid IC, and multi-chip module each having a structure obtained by sealing any element connected to a wiring formed on a support member, according to wire bonding, flip-chip bonding, or soldering, with the resin composition; and BGA (Ball Grid Array), CSP (Chip Size Package), and MCP (Multi Chip Package) each having a structure obtained by mounting any element on the front surface of a support member having a rear surface on which a terminal for connection of a wiring board is formed, connecting such an element to the support member according to connecting bump or wire bonding, and then sealing the element with the resin composition. The resin composition can also be suitably used in a printed wiring board.

Examples of the method of sealing the electronic component device with the resin composition include a low-pressure transfer molding method, an injection molding method, and a compression molding method. In particular, a low-pressure transfer molding method is generally used.

### EXAMPLES

Hereinafter, the embodiments will be more specifically described with reference to Examples, but the scope of the embodiments is not intended to be limited to such Examples.

(Preparation of Resin Composition)

The following components were mixed at a compounding ratio (parts by mass) shown in Table 1, thereby preparing resin compositions of Examples and Comparative Examples.
Epoxy resin 1: bisphenol epoxy resin (Nippon Steel & Sumitomo Metal Corporation, product name “YSLV-80XY”)
Epoxy resin 2: polyfunctional epoxy resin (Mitsubishi Chemical Corporation, product name “1032H60”)
Epoxy resin 3: biphenyl epoxy resin (Mitsubishi Chemical Corporation, product name “YX-4000”)
Curing agent 1: polyfunctional phenol resin (AIR WATER INC, product name “HE910”)
Curing accelerator 1: phosphorus-based curing accelerator
Inorganic filler A1: alumina particle having a volume average particle diameter of 9.0 μm
Inorganic filler A2: alumina particle having a volume average particle diameter of 0.1 μm and a specific surface area of 5.1 m²/g
Inorganic filler S1: silica particle having a volume average particle diameter of 2.6 μm
Inorganic filler S2: silica particle having a volume average particle diameter of 0.03 μm
Inorganic filler S3: silica particle having a volume average particle diameter of 0.8 μm

(Evaluation of Fluidity)

The fluidity of each resin composition was evaluated by a spiral flow test.

Specifically, each resin composition was molded with a mold for spiral flow measurement according to EMMI-1-66, and the distance of flow (cm) of a molded product of the resin composition was measured. Molding of the resin composition was performed using a transfer molding machine under the conditions of a mold temperature of 180° C., a molding pressure of 6.9 MPa, and a curing time of 120 seconds. The results are shown in Table 1.

TABLE 1

| | Example | Example | Example | Comparative | Comparative | Comparative |
|---|---|---|---|---|---|---|
| | 1 | 2 | 3 | Example 1 | Example 2 | Example 3 |
| Epoxy Resin 1 | 70 | 15 | 70 | 70 | 70 | 70 |
| Epoxy Resin 2 | | 60 | | | | |
| Epoxy Resin 3 | 30 | 25 | 30 | 30 | 30 | 30 |
| Curing Agent 1 | 60 | 60 | 60 | 60 | 60 | 60 |
| Curing Accelerator 1 | 4 | 2.5 | 4.5 | 4 | 4 | 4 |
| Inorganic Filler A1 | 2200 | 1350 | 2200 | 2220 | 2200 | 2200 |
| Inorganic Filler A2 | 20 | 200 | 100 | | | |
| Inorganic Filler S1 | | 270 | | | | |
| Inorganic Filler S2 | | | | | 20 | |
| Inorganic Filler S3 | | | | | | 20 |
| Distance of Flow (cm) | 191 | 217 | 245 | 176 | 163 | 167 |

As shown in Table 1, the resin compositions of Examples 1 to 3, in which the inorganic filler included a specific inorganic particle (i.e., inorganic filler A2), were evaluated to be show higher fluidity than the resin composition of Comparative Example 1 in which the inorganic filler included no such specific inorganic particle. The same results were obtained even in a case in which the formulation of the epoxy resin or the formulation of the inorganic filler was changed.

Both of the resin composition of Comparative Example 2 in which the inorganic filler included a silica particle having a volume average particle diameter of 0.03 μm, and the resin composition of Comparative Example 3 in which the inorganic filler included a silica particle having a volume average particle diameter of 0.8 μm were evaluated to show lower fluidity than the resin compositions of Examples.

The disclosures of Japanese Patent Application No. 2016-253846 and Japanese Patent Application No. 2016-253847 are herein incorporated by reference.

All documents, patent applications, and technical standards described herein are herein incorporated by reference, as if each individual document, patent application, and technical standard were specifically and individually indicated to be incorporated by reference.

1. A resin composition, comprising:
a resin; and
an inorganic filler,
wherein the inorganic filler comprises an inorganic particle having an average particle diameter of from 0.07 μm to 0.5 μm.

2. The resin composition according to claim 1, wherein the inorganic particle has a specific surface area of 15 m2/g or less.

3. The resin composition according to claim 1, wherein a proportion of the inorganic particle in the entire inorganic filler is from 3% by mass to 10% by mass.

4. The resin composition according to claim 1, wherein the inorganic particle comprises an alumina particle.

5. The resin composition according to claim 4, wherein a proportion of the inorganic particle in the entire inorganic filler is from 3% by mass to 10% by mass.

6. The resin composition according to claim 1, wherein:
the inorganic filler comprises the inorganic particle and an additional inorganic particle different from the inorganic particle; and
a ratio A/B of a specific gravity A of the inorganic particle to a specific gravity B of the additional inorganic particle is from 0.8 to 1.2.

7. The resin composition according to claim 1, wherein:
the inorganic filler comprises the inorganic particle and an additional inorganic particle different from the inorganic particle; and
the additional inorganic particle comprises an inorganic particle made of the same material as the inorganic particle.

8. The resin composition according to claim 1, for use as a sealant for an electronic component device.

9. An electronic component device, comprising:
an element; and
a cured product of the resin composition according to claim 1 sealing the element.

10. A resin composition, comprising:
a resin; and
an inorganic filler,
wherein the inorganic filler comprises an inorganic particle A having a volume average particle diameter of 0.07 μm to 0.5 μm and an inorganic particle B different from the inorganic particle A, and
a ratio A/B of a refractive index A of a material that is a component of the inorganic particle A to a refractive index B of a material that is a component of the inorganic particle B is from 0.9 to 1.5.

11. A method of producing an electronic component device, the method comprising sealing an element with a resin composition,
wherein the resin composition, comprises:
a resin; and
an inorganic filler, and
wherein the inorganic filler comprises an inorganic particle having an average particle diameter of from 0.07 μm to 0.5 μm.

12. The method according to claim 11, wherein the inorganic particle has a specific surface area of 15 m²/g or less.

13. The method according to claim 11, wherein a proportion of the inorganic particle in the entire inorganic filler is from 3% by mass to 10% by mass.

14. The resin composition according to claim 11, wherein the inorganic particle comprises an alumina particle.

15. The resin composition according to claim 14, wherein a proportion of the inorganic particle in the entire inorganic filler is from 3% by mass to 10% by mass.

16. The resin composition according to claim 11, wherein:
the inorganic filler comprises the inorganic particle and an additional inorganic particle different from the inorganic particle; and
a ratio A/B of a specific gravity A of the inorganic particle to a specific gravity B of the additional inorganic particle is from 0.8 to 1.2.

17. The resin composition according to claim 11, wherein:
the inorganic filler comprises the inorganic particle and an additional inorganic particle different from the inorganic particle; and
the additional inorganic particle comprises an inorganic particle made of the same material as the inorganic particle.
